(19) United States
(12) Patent Application Publication
(10) Pub. No.: US 2008/0192440 A1
(43) Pub. Date: Aug. 14, 2008

(54) Connection assembly

(75) Inventors: Ching-Chang Meng, Taipei (TW); Hung-Ta Huang, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/878,765

(22) Filed: Jul. 26, 2007

(30) Foreign Application Priority Data
Feb. 14, 2007 (CN) 200710079818.7
Feb. 14, 2007 (TW) 096105503

(51) Int. Cl. H05K 7/20

(52) U.S. Cl. 361/719; 361/709

(57) ABSTRACT

A connection assembly for an electronic device includes a hollow sheath and a fastener. In this case, the hollow sheath has a head portion, an axle portion, and a fastening portion. The axle portion connects the head portion and the fastening portion, and the fastening portion has a through hole. The fastener is inserted into the hollow sheath and engaged tightly in the fastening portion. One end of the fastener against the inner bottom surface of the fastening portion.

### BACKGROUND OF THE INVENTION

1. Field of the Invention

The invention relates to a connection assembly and, more particularly, to a connection assembly which can avoid connected items being disassembled.

2. Description of the Related Art

The electronic device, such as computer, has been the necessity for modern people. However, along with the increasing needs of the functions of the electronic devices in recent years, the heat dissipation issue has become one of the problems to be solved.

For example, since the Central Processing Unit (CPU) uses multiple power chips and correspondingly transformers, heat will be generated after operating for a time period. When the temperature increases and exceeds a normal range, the computer cannot work stably and even can be halted. The current cooling system employs a heat dissipation unit assembled on a heat source, such as a motherboard with electric elements, for conducting the heat, and a fan assembled on the heat dissipation unit for producing an air flow to dissipate the heat to the outside.

The current heat dissipation unit and the motherboard are fixed by a fastening element such as screw. The fastening element passes through the through holes of the heat dissipation unit and the motherboard to fix the heat dissipation unit on the CPU. In the current design, if the users assemble the heat dissipation unit to the motherboard and disassemble the heat dissipation unit from the motherboard repeatedly, the CPU of the motherboard would be damaged easily, the through holes would be deformed easily, and labor would be wasted unnecessarily.

To solve the above problem, generally a fastener 1 which can be separated conveniently is introduced to replace the fastener element to fix the heat dissipation unit on the motherboard. As shown in FIG. 1, the current fastener 1 includes a head portion 11, an axle portion 12 and a fastening portion 13. The two ends of the axle portion 12 connect to the head portion 11 and the fastening portion 13 respectively. The diameter of the portion connecting the axle portion 12 and the fastening portion 13 is greater than the diameter of the axle portion 12. A groove G serves as a space for elastic deformation is formed in center of the fastening portion 13 and divides the fastening portion 13 into a left fastening portion 131 and a right fastening portion 132.

Since the diameter of the connection between the axle portion 12 and the fastening portion 13 is also greater than through holes H and H′ on a heat dissipation unit 2 and a motherboard 3, when users want to fix the heat dissipation unit 2 onto the motherboard 3 by the fastener 1, they must exert a force upon the fastener 1 to press the axle portion 12 and the fastening portion 13 passing through the through holes H and H′ on the heat dissipation unit 2 and motherboard 3. During the pressing operation, the left fastening portion 131 and the right fastening portion 132 are closing to the groove G, so that the fastening portion 13 can pass through the through holes H and H′ since its diameter is reduced. After that, the deformation of the fastening portion 13 is restored, and the fastening portion 13 together with the head portion 11 can restrict the position of the fastener 1 to fix the heat dissipation unit 2 and the motherboard 3 tightly. If the users want to disassemble the heat dissipation unit 2 from the motherboard 3, they only need to exert a force to close the left fastening portion 131 and the right fastening portion 132, so that the diameter of the fastening portion 13 is decreased and the fastener 1 can be released from the through holes H and H′.

However, the users can randomly separate the heat dissipation unit 2 and the motherboard 3 by releasing the fastener 1, and the motherboard 3 may be damaged manually. This may increase the difficulty of finding the problems of the products for maintenance engineer, and also increase the difficulty for ascertaining the reason for the damages.

According to above, there is a need for providing a connecting assembly which can avoid the connected items being disassembled randomly.

### BRIEF SUMMARY OF THE INVENTION

According to above, a preferable embodiment of the present invention provides a connecting assembly which can avoid the connected items being disassembled randomly.

A connection assembly according to the invention, which is suitable for an electronic device, includes a hollow sheath and a fastener. Wherein, the hollow sheath includes a head portion, an axle portion, and a fastening portion. The axle portion connects the head portion and the fastening portion. The fastening portion has a through hole. The fastener is inserted into the hollow sheath and engaged tightly in the fastening portion. One end of the fastener againsts with the inner bottom surface of the fastening portion.

A connection assembly according to one embodiment of the invention further includes an elastic element surrounding the axle portion of the hollow sheath and locating between the head portion and the fastening portion of the hollow sheath for better connection.

In one embodiment of the invention of the connection assembly, the electronic device can include a first element and a second element. The first element has a first hole, and the second element has a second hole corresponding to the first hole. When the hollow sheath passes through the first and the second holes, the axle portion of the hollow sheath passes through the first element and the second element. An end of the elastic element againsts the head portion and the other end of the elastic element againsts the first element. The fastening portion againsts the second element for connecting the first and second elements.

In one embodiment of the invention of the connection assembly, wherein the fastening portion includes at least a fastening piece disposed in the through hole. In addition, the fastening portion further includes a guide surface to guide the fastening portion passing the first hole and the second hole. The preferable material of the fastener is metal or plastic but not to limit here. In one embodiment of the invention, the preferable first element of the electronic device is a circuit board, and the preferable second element of the electronic device is a heat dissipation unit, such as a heat sink.

In one embodiment of the invention of the connection assembly, the preferable material of the hollow sheath is macromolecule material, such as plastic.

From above, a connection assembly according to the invention uses a hollow sheath passing through holes of a first element and a second element. A fastening portion and a head portion restrict the hollow sheath to connect the first element and the second element, and then a fastener is inserted in the hollow sheath and engaged in the fastening portion to tight the first element and the second element.

Furthermore, an end of the fastener of the connection assembly of the invention can touch the inner bottom surface of the fastening portion for occupying the fastener at the elastic deformation space of the fastening portion, so that the situation that users press the fastening portion to separate the first and the second elements can be avoid. Therefore, compare with the present technology, the invention can avoid the users separating the connection assembly randomly to reduce the damage ratio of the connected components. Meanwhile, the invention also reduces the difficulty of finding the problems of the damaged products and then clearly determining the source of damages for maintenance engineer.

### BRIEF DESCRIPTION OF THE DRAWINGS

FIG. 1 shows a cross-section diagram of a current fastener fixing a heat dissipation unit and a motherboard.

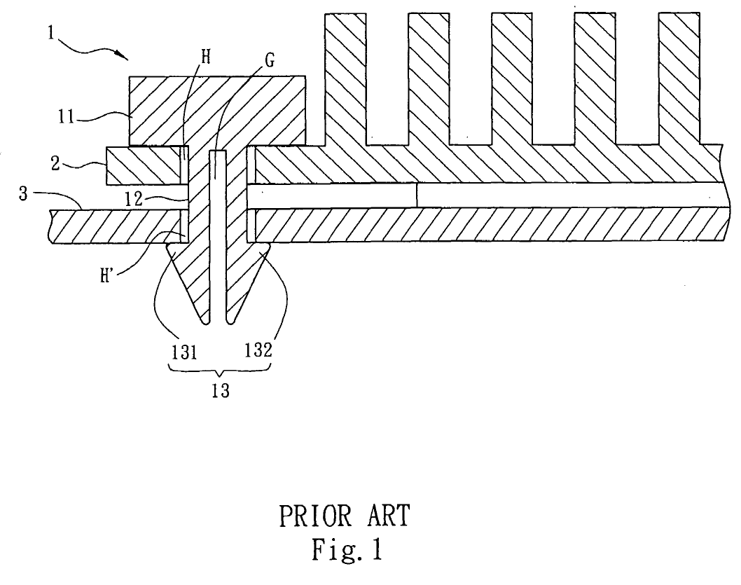

FIG. 2 shows a diagram of an electronic device of one preferable embodiment of the invention.

FIG. 3 shows a cross-section diagram of a connection assembly according to FIG. 2.

FIG. 4 shows a diagram of an electronic device of another preferable embodiment of the invention.

### DETAILED DESCRIPTION OF THE EMBODIMENT

These and other features, aspects, and advantages of the present invention will become better understood with regard to the following description, appended claims, and accompanying drawings.

An electronic device and its connection assembly according to a preferable embodiment of the invention are described below referring to the relating drawings, wherein same elements will be shown as same reference number.

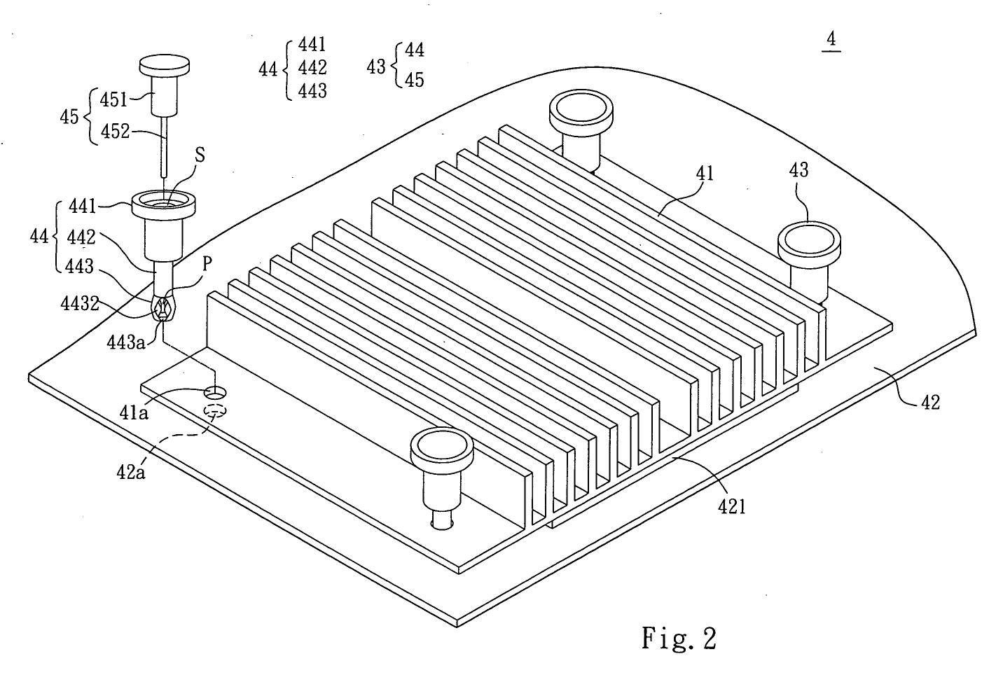

Please refer to FIG. 2, the electronic device 4 according to the embodiment of the invention includes a first element 41, a second element 42, and a connection assembly 43. Wherein, the first element 41 can be a heat dissipation unit, such as a heat sink, and the second element 42 can be a heat source, such as a motherboard or a graphic card with at least one electronic component 421. For example, the electronic component 421 can be a chip. The first element 41 also can be a heat source and the second element 42 can be a heat sink but not limit.

In the embodiment of the invention, the first element 41 is a heat sink, and the second element 42 is a motherboard.

Please refer to FIG. 2, the first element 41 has at least one first hole 41a, and the second element 42 has at least one second hole 42a corresponding to the first hole 41a. The first hole 41a and the second hole 42a are disposed around the first element 41 and the second element 42 respectively.

In addition, the connection assembly 43 of the embodiment of the invention passes the first hole 41a and the second hole 42a to connect the first element 41 and the second element 42, so that the first element 41 and the second element 42 can touch each other efficiently. Therefore, the heat can be conducted from the electronic component 421 to the first element 41 for dissipation.

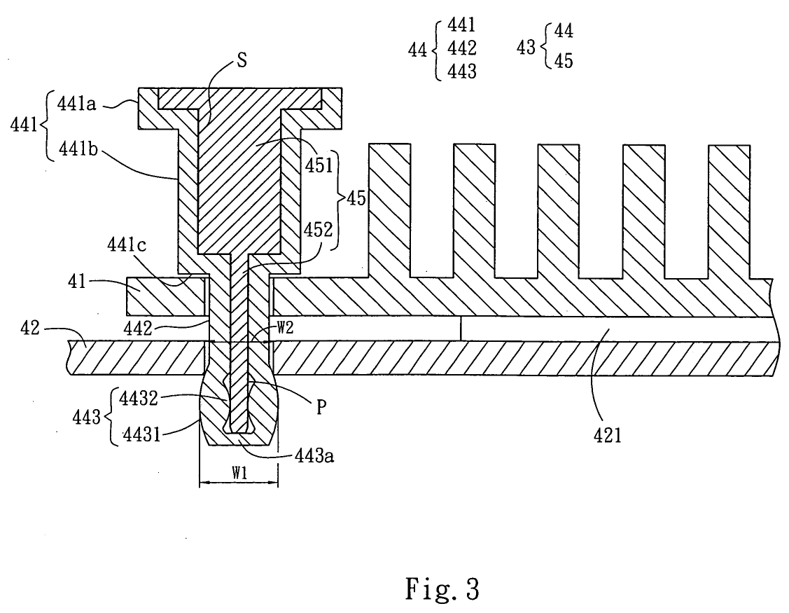

Please refer FIG. 2 and FIG. 3, the connection assembly 43 includes a hollow sheath 44 and a fastener 45, wherein, the interior of the hollow sheath 44 is hollow and formed a space S. The hollow sheath 44 can be made of a macromolecule material such as plastic.

Please refer to FIG. 2 and FIG. 3 again. The hollow sheath 44 has a head portion 441, an axle portion 442, and a fastening portion 443. In the embodiment of the invention, the head portion 441 includes a first part 441a with a discoid structure and a second part 441b with a cylinder structure. The first part 441a and the second part 441b are connected together and the side cross-section of them is a T structure.

The axle portion 442 is between the head portion 441 and the fastening portion 443. In details, the second part 441b of the head portion 441 has a stop surface 441c, and the diameter (or width) of the transverse section of the axle portion 442 is less than the diameter (or width) of the stop surface 441c.

Please refer to FIG. 2 and FIG. 3, the fastening portion 443 away from the head portion 441 has a through hole P for providing a elastic deformation space. The fastening portion 443 has a guide surface 4431 which makes the exterior surface of the fastening portion 443 being an arc. The guide surface 4431 guides the fastening portion 443 passing through the first hole 41a and the second hole 42a smoothly. The fastening portion 443 further includes at least one fastening piece 4432 disposed in the through hole P and opposite to the guide surface 4431. In the embodiment of the invention, the fastening piece 4432 can be a projection.

The largest width W1 of the fastening portion 443 can be greater than the width W2 of the first hole 41a of the first element 41 and the second hole 42a of the second element 42. Therefore, when the connection assembly is going to connect the first element 41 and the second element 42, the operator can exert a force at the hollow sheath 44, and then the fastening portion 443 can pass the first hole 41a and the second hole 42a by the guiding and elastic deformation of the guide surface 4431 of the fastening portion 443.

Since the elasticity of the fastening portion 443 can be restored after the fastening portion 443 passed the first hole 41a and the second hole 42a, the largest width W1 of the fastening portion 443 restores and greater than the width W2 of the first hole 41a and the second hole 42a. Therefore, the hollow sheath 44 is restricted, and the first element 41 and the second element 42 are connected.

At the same time, the resist surface 441c of the head portion 441 againsts the first element 41, and the fastening portion 443 againsts the second element 42. The connection assembly 43 also can pass the second hole 42a and the first hole 41a in turn, and then the stop surface 441c againsts the surface of the second element 42 and the fastening portion 443 againsts the surface of the first element 41.

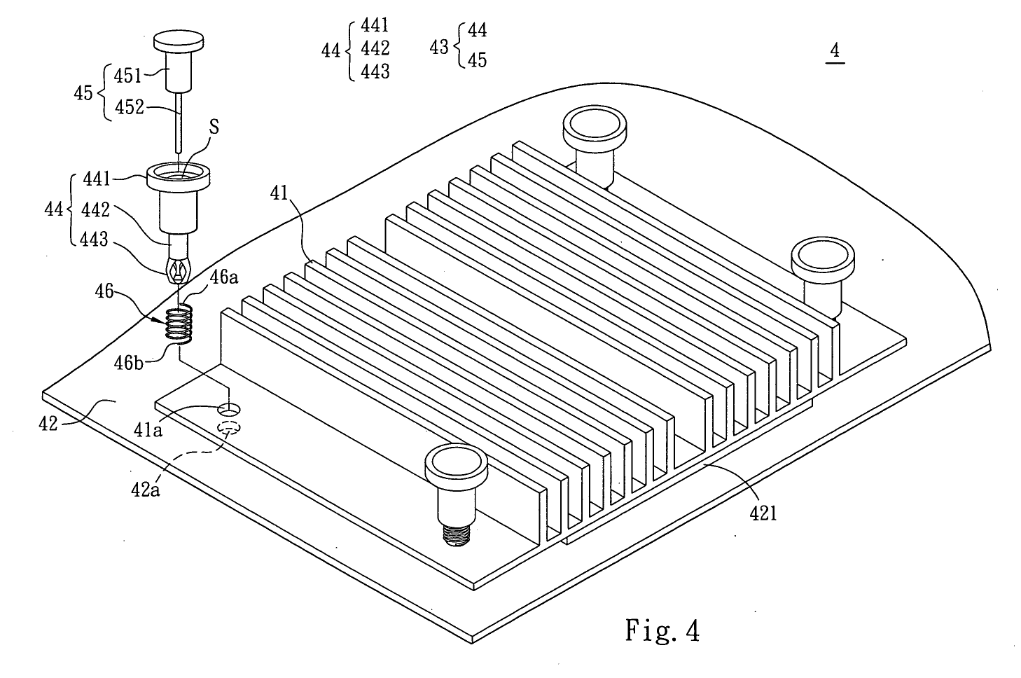

As shown in FIG. 4, the electronic device 4 of the embodiment of the invention further includes an elastic element 46 surrounding the axle portion 442 of the hollow sheath 44 and between the head portion 441 and the fastening portion 443 for tightly connecting the first element 41 and the second element 42 by the hollow sheath 44 and providing cushioning function for the hollow sheath 44 when it passing through the first element 41 and the second element 42.

When the connection assembly 43 connecting to the first element 41 and the second element 42, one end 46a of the elastic element 46 can touch the stop surface 441c and the other end 46b can touch the surface of the first element 41 by the compressibility of the elastic element 46. The first element 41 and the second element 42 can be connected more tightly. In the embodiment of the invention, the elastic element can be a spring or metallic pin.

Please refer to FIG. 3 and FIG. 4, after the hollow sheath 44 passed through the first hole 41a and the second hole 42a, the fastener 45 passes and is wedged into the hollow sheath 44 for preventing the users pressing the fastening portion 443 again to separate the hollow sheath 44 from the first element 41 and the second element 42.

In the embodiment of the invention, the structure of the fastener 45 can be designed according to the space S of the hollow sheath 44, wherein the fastener 45 can be metal or plastic and made by one-batch forming.

In the embodiment of the invention, the fastener 45 has a head portion 451 and an axle portion 452 connected to the head portion 451. The axle portion 452 of the fastener 45 is inserted into the axle portion 442 of the hollow sheath 44 by pressing the head portion 451. One end of the axle portion 452 againsts an inner bottom surface 443a of the fastening portion 443, and the fastener 45 is tightly wedged into the fastening portion 443 by the fastening piece 4432.

By this design, users cannot move the fastener 45 which is inserted in the hollow sheath 44 easily by hand or tools. Users also cannot easily separate the hollow sheath 44 from the first element 41 and the second element 42 due to the elastic deformation of the hollow sheath 44 by pressing the fastening portion 443.

From above, a connection assembly according to the invention uses a hollow sheath to pass through holes of a first element and a second element, and a fastening portion and a head portion to restrict the hollow sheath for connecting the first element and the second element. After that, a fastener is inserted the hollow sheath and wedged into the fastening portion, and one end of the fastener againsts an inner bottom surface of the fastening portion, so that the fastener can occupy a elastic deformation space of the fastening portion. Therefore, the situation that the users press the fastening portion to release the first and the second elements can be avoided. Compare with the current technology, the present invention can avoid the users separating the connection assembly randomly to reduce the damage ratio of the connected components. Meanwhile, the invention also reduces the difficulty of finding the problems of the damaged products and then clearly determining the source of damages for maintenance engineer.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A connection assembly for an electronic device, comprising:
a hollow sheath having a head portion, an axle portion, and a fastening portion, the axle portion connecting the head portion and the fastening portion, the fastening portion having a through hole; and
a fastener inserted into the hollow sheath and engaged tightly in the fastening portion, one end of the fastener against the inner bottom surface of the fastening portion.

2. The connection assembly according to the claim 1, further comprising:
an elastic element surrounding the axle portion of the hollow sheath and being provided between the head portion and the fastening portion of the hollow sheath.

3. The connection assembly according to the claim 1, wherein the electronic device comprises a first element and a second element, the first element having a first hole, the second element having a second hole corresponding to the first hole.

4. The connection assembly according to the claim 3, wherein when the hollow sheath passing through the first hole and the second hole, the axle portion of the hollow sheath passes through the first element and the second element, one end of the elastic element againsts the head portion and the other end of the elastic element againsts the first element, the fastening portion againsts the second element for connecting the first element and the second element.

5. The connection assembly according to the claim 1, wherein the fastening portion comprises at least one fastening piece.

6. The connection assembly according to the claim 5, wherein the fastening piece is disposed in the through hole.

7. The connection assembly according to the claim 3, wherein the fastening portion has a guiding surface for guiding the fastening portion passing the first hole and the second hole.

8. The connection assembly according to the claim 1, wherein the material of the hollow sheath is plastic.

9. The connection assembly according to the claim 1, wherein the material of the fastener is metal or plastic.

10. The connection assembly according to the claim 3, wherein the first element is a heat dissipation unit and the second element is a circuit board.
